(19) United States
(12) Patent Application Publication
(10) Pub. No.: US 2016/0240547 A1
(43) Pub. Date: Aug. 18, 2016

(54) SEMICONDUCTOR MEMORY DEVICE

(71) Applicant: Kabushiki Kaisha Toshiba, Minato-ku (JP)

(72) Inventors: Masayoshi TAGAMI, Kuwana (JP); Yoshiaki FUKUZUMI, Yokkaichi (JP)

(73) Assignee: Kabushiki Kaisha Toshiba, Minato-ku (JP)

(21) Appl. No.: 14/849,970

(22) Filed: Sep. 10, 2015

Related U.S. Application Data
(60) Provisional application No. 62/117,735, filed on Feb. 18, 2015.

(51) Int. Cl. H01L 27/115

(52) U.S. Cl. CPC H01L 27/11565; H01L 27/1157

(57) ABSTRACT

According to one embodiment, a semiconductor memory device includes first plate-like members, a first wiring, a second plate-like member, a second wiring, first to third semiconductor pillars, a memory film, first to third contacts, first to third plugs, and third wirings. The first wiring is placed between two adjacent ones of the first plate-like members. The second plate-like member is placed on the first wiring. The second wiring is placed between the first plate-like member and the second plate-like member. The first contact is connected to the first semiconductor pillar. The first plug is connected to the first contact. Distance between the central axis of the first plug and the central axis of the second plug in the second direction is different from distance between the central axis of the second plug and the central axis of the third plug.

### CROSS-REFERENCE TO RELATED APPLICATIONS

This application is based upon and claims the benefit of priority from U.S. Provisional Patent Application 62/117,735, filed on Feb. 18, 2015; the entire contents of which are incorporated herein by reference.

### FIELD

Embodiments described herein relate generally to a semiconductor memory device.

### BACKGROUND

Conventionally, NAND flash memories have increased the degree of integration by miniaturization of the planar structure and reduced the bit cost. However, the miniaturization of the planar structure is approaching the limit. Thus, technologies for vertically stacking memory cells have been proposed in recent years. However, memory devices of the stacked type also need miniaturization of the planar structure in order to achieve higher integration.

### BRIEF DESCRIPTION OF THE DRAWINGS

FIG. 1 is a plan view showing a semiconductor memory device according to a first embodiment;

FIG. 2 is a sectional view taken along line A-A′ of FIG. 1;

FIG. 3 is a plan view showing a semiconductor memory device according to a second embodiment;

FIG. 4 is a sectional view taken along line B-B′ of FIG. 3;

FIG. 5 is a plan view showing a semiconductor memory device according to a variation of the second embodiment; and

FIG. 6 is a plan view showing a semiconductor memory device according to a third embodiment.

### DETAILED DESCRIPTION

According to one embodiment, a semiconductor memory device includes a plurality of first plate-like members extending in a first direction, a first wiring placed between two adjacent ones of the plurality of first plate-like members and extending in the first direction, a second plate-like member placed on the first wiring and extending in the first direction, a second wiring placed between one of the first plate-like members and the second plate-like member and extending in the first direction, first to third semiconductor pillars extending in a third direction, a memory film provided between the first wiring and one of the first to third semiconductor pillars, first to third contacts provided on the first to third semiconductor pillars, first to third plugs provided on the first to third contacts, and third wirings provided on the first to third plugs and extending in the second direction. The plurality of first plate-like members are spaced from each other in a second direction. The second direction crosses the first direction. The third direction crosses both the first direction and the second direction. The first to third semiconductor pillars pierces the first wiring and the second wiring. The first to third contacts are connected to the first to third semiconductor pillars, respectively. The first to third plugs are connected to the first to third contacts, respectively. Central axes of the first to third plugs are shifted with respect to central axes of the first to third contacts, respectively. The first to third plugs are arranged in this order in the second direction. Distance between the central axis of the first plug and the central axis of the second plug in the second direction is different from distance between the central axis of the second plug and the central axis of the third plug in the second direction. The third wirings are connected to the first to third plugs, respectively.

Embodiments will now be described with reference to the drawings.

### First Embodiment

First, a first embodiment is described.

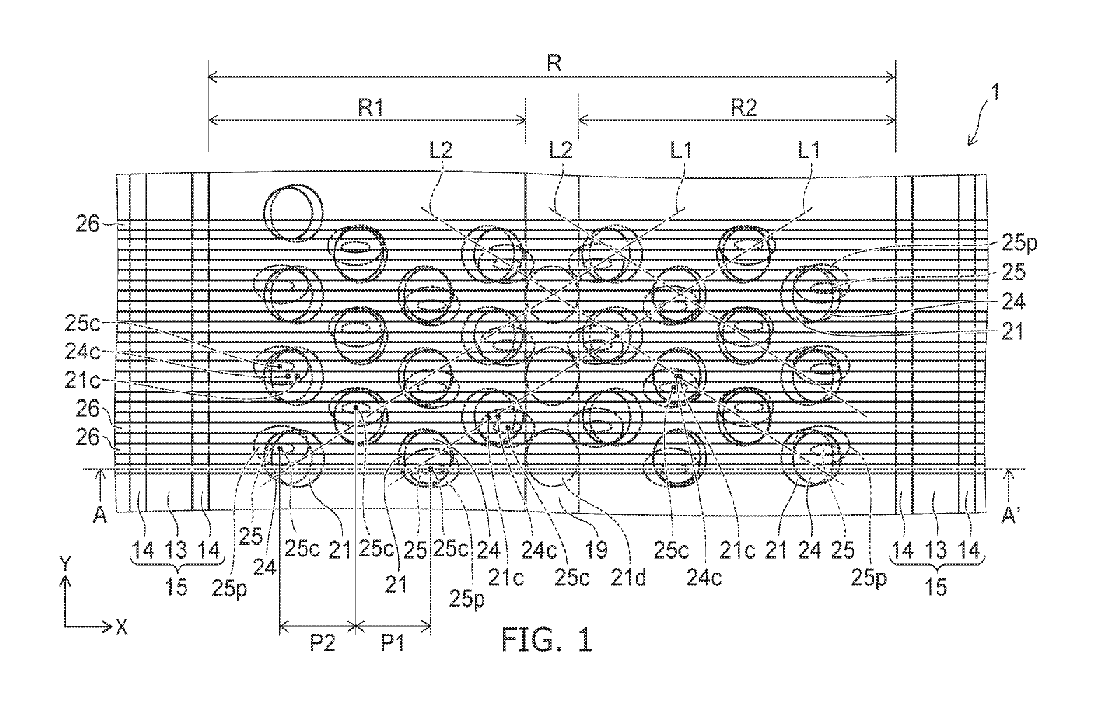

FIG. 1 is a plan view showing a semiconductor memory device according to this embodiment.

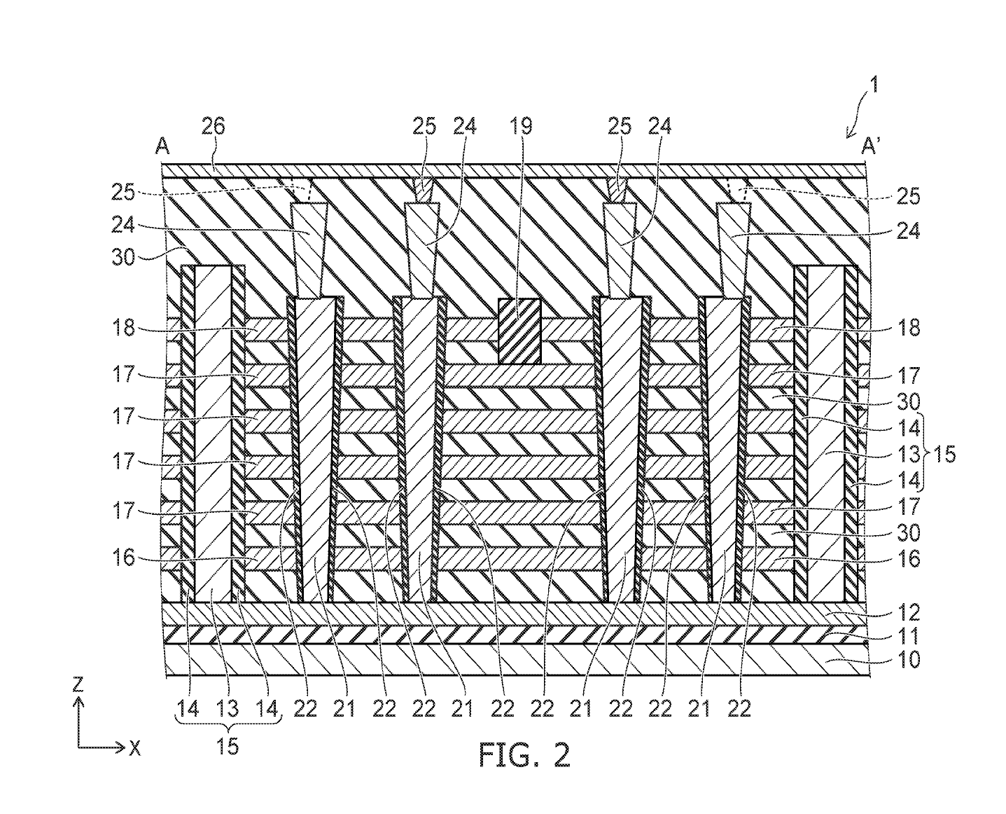

FIG. 2 is a sectional view taken along line A-A′ of FIG. 1.

As shown in FIGS. 1 and 2, the semiconductor memory device 1 according to this embodiment includes a silicon substrate 10. In the following, for convenience of description, an XYZ orthogonal coordinate system is used in this specification. Two directions parallel to the upper surface of the silicon substrate 10 and orthogonal to each other are referred to as “X-direction” and “Y-direction”. The direction perpendicular to the upper surface of the silicon substrate 10 is referred to as “Z-direction”.

An insulating film 11 made of e.g. silicon oxide is provided on the silicon substrate 10. A cell source line 12 is provided on the insulating film 11. The cell source line 12 includes e.g. a polysilicon layer (not shown), a tungsten layer (not shown), and a polysilicon layer (not shown) stacked in this order. The cell source line 12 is a plate-like conductive member spread along the XY-plane.

A plurality of source electrodes 13 extending in the Y-direction are provided at regular spacings on the cell source line 12. The source electrode 13 is shaped like a plate along the YZ-plane. The lower end of the source electrode 13 is connected to the cell source line 12. An insulating film 14 is formed on both side surfaces of the cell source line 12. One source electrode 13 and two insulating films 14 constitute a plate-like member 15.

On the cell source line 12, e.g. one lower select gate electrode 16, a plurality of word lines 17, and e.g. one upper select gate electrode 18 are stacked upward in this order. The lower select gate electrode 16, the word lines 17, and the upper select gate electrode 18 are spaced from each other in the Z-direction and extend in the Y-direction. The lower select gate electrode 16 and the word lines 17 are divided by the plate-like member 15.

An insulating member 19 extending in the Y-direction is provided on the word line 17 and between two adjacent plate-like members 15. The insulating member 19 is located at an equal distance from the two plate-like members 15. The upper select gate electrode 18 is divided by the plate-like member 15 and the insulating member 19. Thus, the arrangement pitch of the upper select gate electrodes 18 in the X-direction is half the arrangement pitch of the lower select gate electrodes 16 and the arrangement pitch of the word lines 17. In FIG. 1, the cell source line 12, the lower select gate electrode 16, the word line 17, and the upper select gate electrode 18 are not shown for clarity of illustration.

A plurality of silicon pillars 21 extending in the Z-direction are provided so as to pierce the lower select gate electrode 16, the plurality of word lines 17, and the upper select gate electrode 18. The lower end part of the silicon pillar 21 is connected to the cell source line 12. The silicon pillar 21 is shaped like e.g. a circle as viewed in the Z-direction.

A memory film 22 is provided on the side surface of the silicon pillar 21. That is, the memory film 22 is placed between the silicon pillar 21 and the lower select gate electrode 16, between the silicon pillar 21 and the word line 17, and between the silicon pillar 21 and the upper select gate electrode 18. The memory film 22 is a film capable of accumulating charge.

In the memory film 22, a tunnel insulating layer (not shown), a charge accumulation layer (not shown), and a block insulating layer (not shown) are stacked sequentially from the silicon pillar 21 side. The tunnel insulating layer is a layer that is normally insulating. However, the tunnel insulating layer passes a tunnel current under application of a prescribed voltage within the range of the driving voltage of the semiconductor memory device 1. The charge accumulation layer is a layer capable of retaining charge. The charge accumulation layer includes e.g. electron trap sites. The block insulating layer is a layer passing substantially no current even under application of voltage within the range of the driving voltage of the semiconductor memory device 1. The block insulating layer is formed from a material having higher permittivity than the material forming the tunnel insulating layer.

A contact 24 extending in the Z-direction is provided on the silicon pillar 21. The silicon pillar 21 is in one-to-one correspondence with the contact 24. The upper end of one silicon pillar 21 is connected to the lower end of one contact 24. As viewed in the Z-direction, the contact 24 is shaped like e.g. a circle, and has a slightly smaller size than the silicon pillar 21. In the Z-direction, the lower end of the contact 24 is located below the upper end of the source electrode 13. The upper end of the contact 24 is located above the upper end of the source electrode 13.

A plug 25 is provided on the contact 24. The contact 24 is in one-to-one correspondence with the plug 25. The upper end of one contact 24 is connected to the lower end of one plug 25. As viewed in the Z-direction, the plug 25 is shaped like an oval. Its long diameter direction is the X-direction. As viewed in the Z-direction, the long diameter of the plug 25 is smaller than the diameter of the contact 24.

A plurality of bit lines 26 extending in the X-direction are provided on the plug 25. As viewed in the Z-direction, the width of the bit line 26 is nearly equal to the short diameter of the plug 25. The upper end of each plug 25 is connected to one bit line 26. However, multiple plugs 25 are connected to one bit line 26.

An interlayer insulating film 30 made of e.g. silicon oxide is provided among the cell source line 12, the lower select gate electrode 16, the word line 17, the upper select gate electrode 18, the silicon pillar 21, the contact 24, the plug 25, and the bit line 26.

In the semiconductor memory device 1, a lower select transistor is formed for each crosspoint of the silicon pillar 21 and the lower select gate electrode 16. A memory cell transistor including the memory film 22 is formed for each crosspoint of the silicon pillar 21 and the word line 17. An upper select transistor is formed for each crosspoint of the silicon pillar 21 and the upper select gate electrode 18. One upper select transistor, a plurality of memory cell transistors, and one lower select transistor are connected in series between the bit line 26 and the cell source line 12 to constitute a NAND string.

Next, the planar placement, i.e., the placement as viewed in the Z-direction, of the silicon pillars 21, the contacts 24, the plugs 25, and the bit lines 26 is described.

In the following description, the region between adjacent plate-like members 15 is referred to as “region R”. One of the regions between the plate-like member 15 and the insulating member 19 is referred to as “sub-region R1”, and the other is referred to as “sub-region R2”. The planar placement of the silicon pillars 21, the contacts 24, and the plugs 25 in the sub-region R1 is symmetric with the planar placement of the silicon pillars 21, the contacts 24, and the plugs 25 in the sub-region R2 with respect to the center plane of the insulating member 19. In the semiconductor memory device 1, multiple regions R are arranged along the X-direction. However, all the regions R are identical in structure.

First, the planar placement of the silicon pillars 21 is described.

In the region R, the silicon pillars 21 include dummy silicon pillars (hereinafter referred to as “dummy pillars 21d”). The silicon pillars 21 are arranged periodically in a zigzag pattern. More specifically, the silicon pillars 21 and the dummy pillars 21d are placed at lattice points of a virtual lattice constituted by virtual straight lines L1 and L2. The straight lines L1 and L2 lie in the XY-plane, cross both the X-direction and the Y-direction, and extend in directions crossing each other. As viewed in the Z-direction, the figure connecting the centers of three adjacent silicon pillars is e.g. a regular triangle.

The silicon pillars 21 and the dummy pillars 21d are arranged in nine rows along the X-direction in the region R. This pattern is hereinafter referred to as “ninefold zigzag”. The X-direction central part of the region R includes one row composed of dummy pillars 21d and extending in the Y-direction. Each of the sub-regions R1 and R2 on both sides thereof includes four rows each composed of silicon pillars 21 and extending in the Y-direction. Thus, the placement of the silicon pillars 21 is restricted by the plate-like member 15 and the insulating member 19. The phase of the arrangement of the silicon pillars 21 and the dummy pillars 21d is shifted by half the pitch between the adjacent rows. The dummy pillars 21d are placed in the insulating member 19.

The dummy pillar 21d is provided in order to facilitate light exposure by imparting periodicity to the exposure pattern when forming a memory hole in which a memory film 22 and a silicon pillar 21 are to be formed. In this embodiment, in the lithography step for forming memory holes, SRAFs (sub-resolution assist features) not imaged on the resist are placed in the region of the exposure mask corresponding to the dummy pillars 21d. Thus, at the position of the dummy pillar 21d, no memory hole is formed, and hence the dummy pillar 21d is not actually formed, either. Accordingly, in FIG. 2, the dummy pillar 21d is not shown. In the case where the dummy pillar 21d is not actually formed, the dummy pillar 21d may be placed also in the source electrode 13 and in its neighborhood.

Alternatively, a memory hole may be formed at the position of the dummy pillar 21d, and a memory film 22 and a silicon pillar may be embedded in this memory hole. In this case, the dummy pillar 21d actually exists. However, the contact 24 and the plug 25 are not provided on the dummy pillar 21d. Thus, the dummy pillar 21d is not connected to the bit line 26. Accordingly, the dummy pillar 21d does not function as a memory cell transistor. Alternatively, an insulating material may be embedded in the memory hole.

Next, the planar placement of the contacts 24 is described.

In the example shown in FIG. 1, the central axis 24c of the contact 24 is shifted toward the nearest plate-like member 15 or insulating member 19 with respect to the central axis 21c of the silicon pillar 21. More specifically, in the four rows of silicon pillars 21 arranged in the sub-region R1, the central axis 24c of the two rows of contacts 24 placed on the plate-like member 15 side is shifted to the plate-like member 15 side with respect to the central axis 21c of the silicon pillar 21 connected with the corresponding contact 24. The shift amount of the central axis 24c of the contact 24 belonging to the row nearest to the plate-like member 15 is larger than the shift amount of the central axis 24c of the contact 24 belonging to the row second nearest to the plate-like member 15. Furthermore, the central axis 24c of the two rows of contacts 24 placed on the insulating member 19 side is shifted to the insulating member 19 side with respect to the central axis 21c of the silicon pillar 21 connected with the corresponding contact 24. The shift amount of the central axis 24c of the contact 24 belonging to the row nearest to the insulating member 19 is larger than the shift amount of the central axis 24c of the contact 24 belonging to the row second nearest to the insulating member 19. As a result, the distance between the contacts 24 is longer than the distance between the silicon pillars 21. This also applies to the sub-region R2.

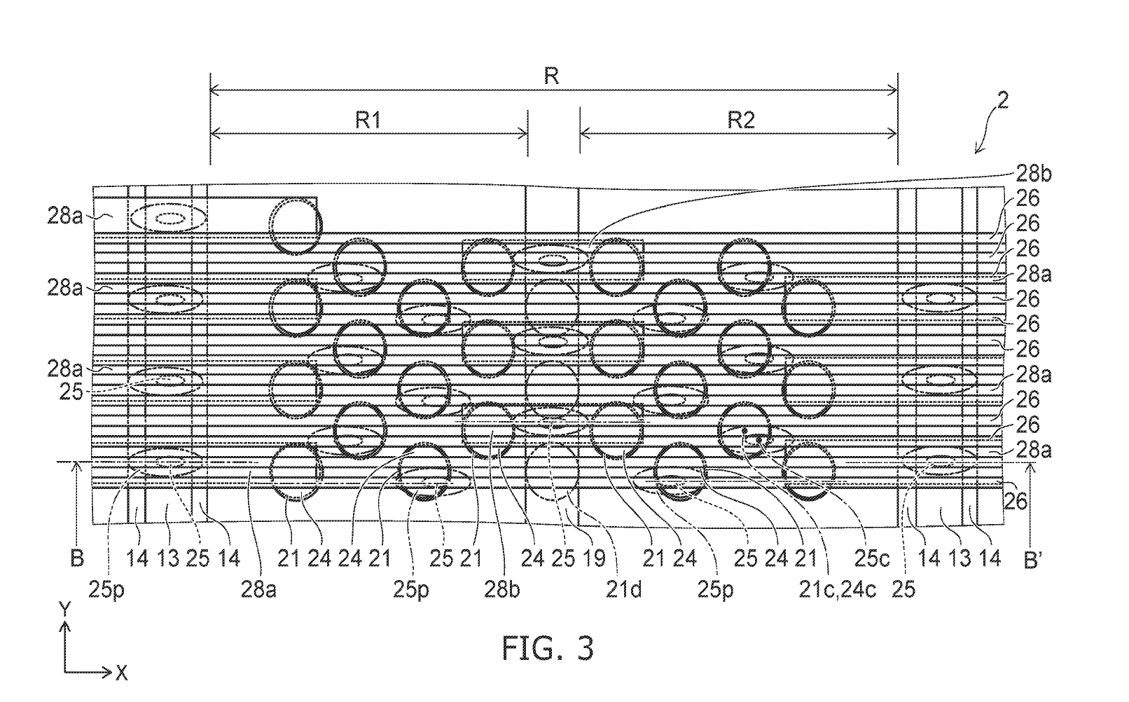

As shown in FIG. 3 described later, the central axis 24c of the contact 24 may coincide with the central axis 21c of the silicon pillar 21. In this case, the planar placement of the contacts 24 coincides with the planar placement of the silicon pillars 21.

Next, the planar placement of the plugs 25 is described.

The central axis 25c of the plug 25 is shifted toward the nearest plate-like member 15 or insulating member 19 with respect to the central axis 24c of the contact 24. However, the long diameter of the plug 25 is smaller than the diameter of the contact 24. Thus, the entirety of the plug 25 is fitted in the region directly above the contact 24. The plug 25 is placed above the plate-like member 15 and the insulating member 19. Thus, the plate-like member 15 and the insulating member 19 do not restrict the planar placement of the plug 25. As a result, in the sub-region R1, the distance P1 between the central axes 25c of the two rows of plugs 25 arranged in the X-direction central part is different from the distance P2 between the central axes 25c of the two rows of plugs 25 arranged in the X-direction end part. For instance, the distance P1 is longer than the distance P2. This also applies to the sub-region R2. In FIG. 1, the exposure pattern 25p of the plug 25 is also shown. The exposure pattern 25p is also shaped like an oval with the long diameter direction being the X-direction.

Furthermore, the central axis 25c of the plug 25 is shifted to one of the Y-direction sides with respect to the central axis 24c of the contact 24. In the sub-region R1, the plugs 25 connected to the two rows of contacts 24 placed on the plate-like member 15 side are shifted to one Y-direction side with respect to the contacts 24. The plugs 25 connected to the two rows of contacts 24 placed on the insulating member 19 side are shifted to the other Y-direction side with respect to the contacts 24. Thus, in the sub-region R1, the Y-direction positions of two plugs 25 connected to two contacts 24 located at the same position in the Y-direction are different from each other. As a result, the distance between the plugs 25 is longer than the distance between the contacts 24. This also applies to the sub-region R2.

Each arrangement pitch of the silicon pillars 21, the contacts 24, and the plugs 25 arranged in a row along the Y-direction is four times the arrangement pitch of the bit lines 26. Two bit lines 26 pass through the region directly above one silicon pillar 21. As described above, in the sub-region R1, the Y-direction positions of two plugs 25 connected to two contacts 24 located at the same position in the Y-direction are different from each other. Thus, these two plugs 25 are connected to different bit lines 26. This also applies to the sub-region R2.

Thus, one bit line 26 is connected with one plug 25 placed in the sub-region R1 and one plug 25 placed in the sub-region R2. In units of four bit lines 26 arranged consecutively, the X-direction position of the plugs 25 connected to these bit lines 26 is periodically changed. That is, the plugs 25 are placed in a fourfold zigzag pattern.

Next, the operation and effect of this embodiment are described.

The distance P1 and the distance P2 between the central axes 25c of the plugs 25 in the X-direction are made different in this embodiment. Thus, it is easy to avoid the problem of short circuit between the plugs 25 that may occur when the arrangement pitch of the plugs 25 in the X-direction is reduced by equalizing the distance P1 and the distance P2. This can suppress the shift amount of the central axis 24c of the contact 24 with respect to the central axis 21c of the silicon pillar 21. In some cases, the shift amount can be set to zero. This can sufficiently ensure the distance between the source electrode 13 and the contact 24 placed at the position nearest to the source electrode 13. As a result, the source electrode 13 is less likely to be brought into contact with the contact 24 even if the internal stress or the like occurring during processing distorts the silicon substrate 10 and warps the source electrode 13. Thus, the margin between the source electrode 13 and the contact 24 can be reduced. This facilitates miniaturization of the planar structure.

In this embodiment, provision of dummy pillars 21d enables periodic arrangement of the silicon pillars 21 and the dummy pillars 21d in spite of the presence of the plate-like member 15 and the insulating member 19. This facilitates lithography for forming the silicon pillars 21.

Furthermore, the plug 25 is shifted toward the plate-like member 15 or the insulating member 19 with respect to the region directly above the silicon pillar 21. Thus, the distance between the plugs 25 can be made longer than the distance between the silicon pillars 21. This facilitates lithography for forming the plugs 25.

Moreover, the contact 24 is shifted toward the plate-like member 15 or the insulating member 19 with respect to the region directly above the silicon pillar 21. Thus, the contact 24 can be reliably brought into contact with both the silicon pillar 21 and the plug 25.

Thus, according to this embodiment, the distance between the plugs 25 is made longer than the distance between the silicon pillars 21. This enables reliable connection between the silicon pillar 21 and the plug 25 while facilitating lithography. As a result, miniaturization of the planar structure is easy in the semiconductor memory device according to this embodiment.

### Second Embodiment

Next, a second embodiment is described.

FIG. 3 is a plan view showing a semiconductor memory device according to this embodiment.

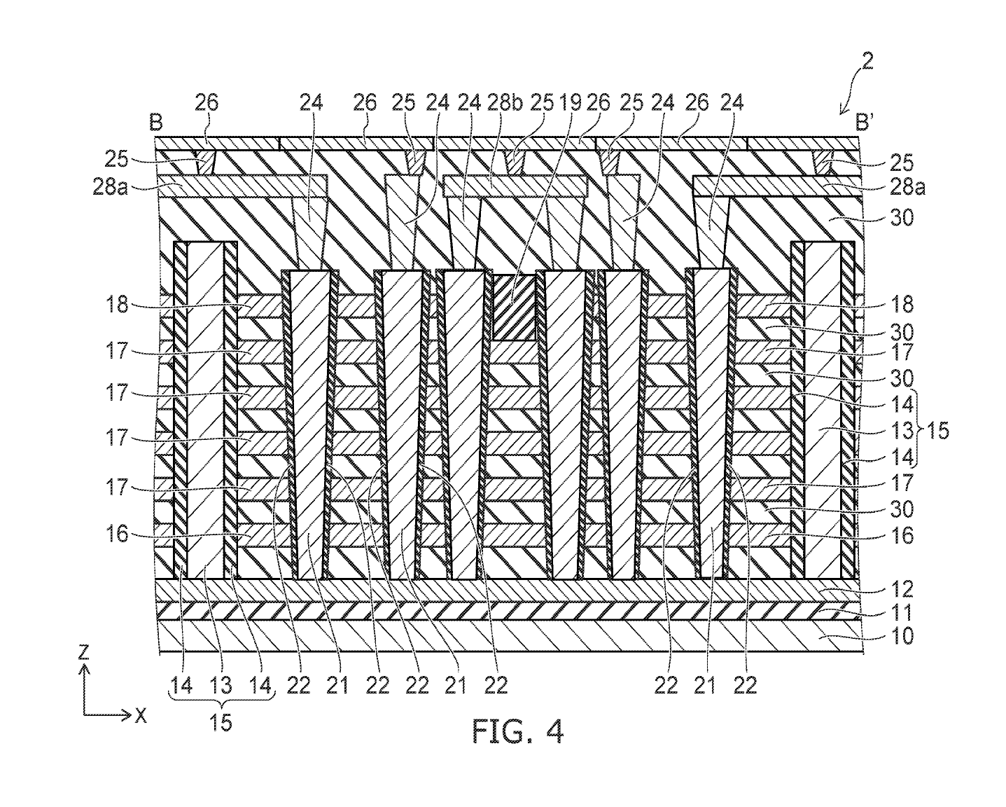

FIG. 4 is a sectional view taken along line B-B′ of FIG. 3.

As shown in FIGS. 3 and 4, in the semiconductor memory device 2 according to this embodiment, intermediate wirings 28a and 28b are provided between part of the contacts 24 and the plugs 25. Part of the contacts 24 are bundled by the intermediate wirings 28a and 28b to reduce the number of plugs 25. Furthermore, the long diameter, i.e., X-direction length, of the exposure pattern 25p of the plug 25 is longer in this embodiment than in the above first embodiment (see FIG. 1).

This embodiment is specifically described in the following.

In the semiconductor memory device 2, the contact 24 is placed directly above the silicon pillar 21. That is, the central axis 24c of the contact 24 is not substantially shifted with respect to the central axis 21c of the silicon pillar 21. Furthermore, an intermediate wiring 28a extending in the X-direction astride the plate-like member 15 is provided so as to connect two adjacent contacts 24 sandwiching the plate-like member 15. An intermediate wiring 28b extending in the X-direction astride the insulating member 19 is provided so as to connect two adjacent contacts 24 sandwiching the insulating member 19.

Both X-direction end parts of the intermediate wiring 28a are placed directly above the two contacts 24 nearest to the plate-like member 15 in the adjacent regions R. The X-direction central part of the intermediate wiring 28a is placed directly above the plate-like member 15. Both X-direction end parts of the intermediate wiring 28b are placed directly above the two contacts 24 nearest to the insulating member 19 in one region R. The X-direction central part of the intermediate wiring 28b is placed directly above the insulating member 19. The length of the plate-like member 15 in the X-direction is longer than the length of the insulating member 19. The intermediate wiring 28a is longer than the intermediate wiring 28b.

The arrangement pitch of the intermediate wirings 28a in the Y-direction is four times the arrangement pitch of the bit lines 26. For instance, the width of the intermediate wiring 28a is approximately twice the arrangement pitch of the bit lines 26. The distance between the intermediate wirings 28a in the Y-direction is also approximately twice the arrangement pitch of the bit lines 26. This also applies to the intermediate wirings 28b. However, the intermediate wirings 28a and the intermediate wirings 28b are arranged in a zigzag pattern. That is, the position of the intermediate wiring 28a in the Y-direction is shifted from the position of the intermediate wiring 28b nearest to this intermediate wiring 28a by twice the arrangement pitch of the bit lines 26.

One plug 25 is provided on the X-direction central part of the intermediate wiring 28a, i.e., directly above the source electrode 13, and connected to the intermediate wiring 28a. One plug 25 is provided on the X-direction central part of the intermediate wiring 28b, i.e., directly above the insulating member 19, and connected to the intermediate wiring 28b. That is, the contact 24 connected to the intermediate wiring 28a or 28b is not directly connected to the plug 25, but connected to the plug 25 through the intermediate wiring 28a or 28b. The plug 25 is connected to the bit line 26.

Thus, one contact 24 is connected to the silicon pillar 21 belonging to the row nearest to the source electrode 13 in the four rows of silicon pillars 21 placed in the sub-region R1 of one region R. Another contact 24 is connected to the silicon pillar 21 belonging to the row nearest to the source electrode 13 in the four rows of silicon pillars 21 placed in the sub-region R2 of the adjacent region R. The former contact 24 is connected to the latter contact 24 through the intermediate wiring 28a, and connected to the bit line 26 through this intermediate wiring 28a and one common plug 25.

One contact 24 is connected to the silicon pillar 21 belonging to the row nearest to the insulating member 19 in the four rows of silicon pillars 21 placed in the sub-region R1 of one region R. Another contact 24 is connected to the silicon pillar 21 belonging to the row nearest to the insulating member 19 in the four rows of silicon pillars 21 placed in the sub-region R2 of the same region R. The former contact 24 is connected to the latter contact 24 through the intermediate wiring 28b, and connected to the bit line 26 through this intermediate wiring 28b and one common plug 25.

On the other hand, the contact 24 connected to the silicon pillar 21 belonging to the two central rows in the four rows of silicon pillars 21 placed in the sub-region R1 is not connected to the intermediate wiring. This contact 24 is directly in contact with the plug 25, and connected to the bit line 26 through the plug 25. This also applies to the sub-region R2.

Thus, the X-direction position of the plug 25 connected to the bit line 26 is periodically changed in units of four bit lines 26 arranged consecutively. For instance, in the example shown in FIG. 3, the bit line 26 placed at the lowermost place in the figure is connected without the intermediary of the intermediate wiring with the contact 24 in the third row counted from the source electrode 13. The bit line 26 placed at the second place from the bottom in the figure is connected through the intermediate wiring 28a with the contact 24 in the first row counted from the source electrode 13. The bit line 26 placed at the third place from the bottom in the figure is connected without the intermediary of the intermediate wiring with the contact 24 in the second row counted from the source electrode 13. The bit line 26 placed at the fourth place from the bottom in the figure is connected through the intermediate wiring 28b with the contact 24 in the fourth row counted from the source electrode 13, i.e., in the row nearest to the insulating member 19. Also for the bit lines 26 placed at the fifth and subsequent places from the bottom in the figure, the configuration of the arrangement is periodically changed in a similar pattern. The four bit lines 26 constituting one unit are connected with the four rows of contacts 24 in the sub-region R1 and the four rows of contacts 24 in the sub-region R2, respectively.

On the other hand, the contact 24 connected with one bit line 26 belongs to the same row in any region R. In the example shown in FIG. 3, the lowermost bit line 26 in the figure is connected to the contact 24 in the second row counted from the insulating member 19 in any region R. That is, in the semiconductor memory device 2, multiple regions R are arranged along the X-direction, but are all identical in structure.

Next, the operation and effect of this embodiment are described.

The intermediate wirings 28a and 28b are provided in this embodiment. With regard to the contacts 24 placed in both X-direction end parts of the sub-region R1 and the sub-region R2, two contacts 24 are connected to one plug 25 through one intermediate wiring. Thus, the contacts 24 placed in both X-direction end parts of the sub-region R1 and the sub-region R2 do not need to be directly connected with the plug 25. Accordingly, there is no need to shift the central axis of the contact 24 with respect to the central axis of the silicon pillar 21 in order to ensure the contact area with the plug 25. This can sufficiently ensure the distance between the source electrode 13 and the contact 24 placed at the position nearest to the source electrode 13. As a result, the source electrode 13 is less likely to be brought into contact with the contact 24 even if the internal stress or the like occurring during processing distorts the silicon substrate 10 and warps the source electrode 13. Thus, the margin between the source electrode 13 and the contact 24 can be reduced. This also facilitates miniaturization of the planar structure.

Furthermore, no intermediate wiring is provided in the X-direction central part of the sub-region R1 and the sub-region R2. The two rows of contacts 24 placed in the X-direction central part are directly connected to the plugs 25. Thus, the number of intermediate wirings can be made smaller, and the arrangement pitch of the intermediate wirings 28a and 28b in the Y-direction can be made longer than in the case of connecting all the contacts 24 to the intermediate wirings. This facilitates forming the intermediate wirings 28a and 28b.

Furthermore, in this embodiment, two contacts 24 are connected to one plug 25 through the intermediate wirings 28a and 28b. Thus, the number of plugs 25 can be reduced. This increases the degree of freedom of the placement of the plugs 25. Furthermore, the long diameter of the exposure pattern 25p of the plug 25 can be made longer. This facilitates shrinking the plug 25.

The configuration, operation, and effect of this embodiment other than the foregoing are similar to those of the above first embodiment.

### Variation of the Second Embodiment

Next, a variation of the second embodiment is described.

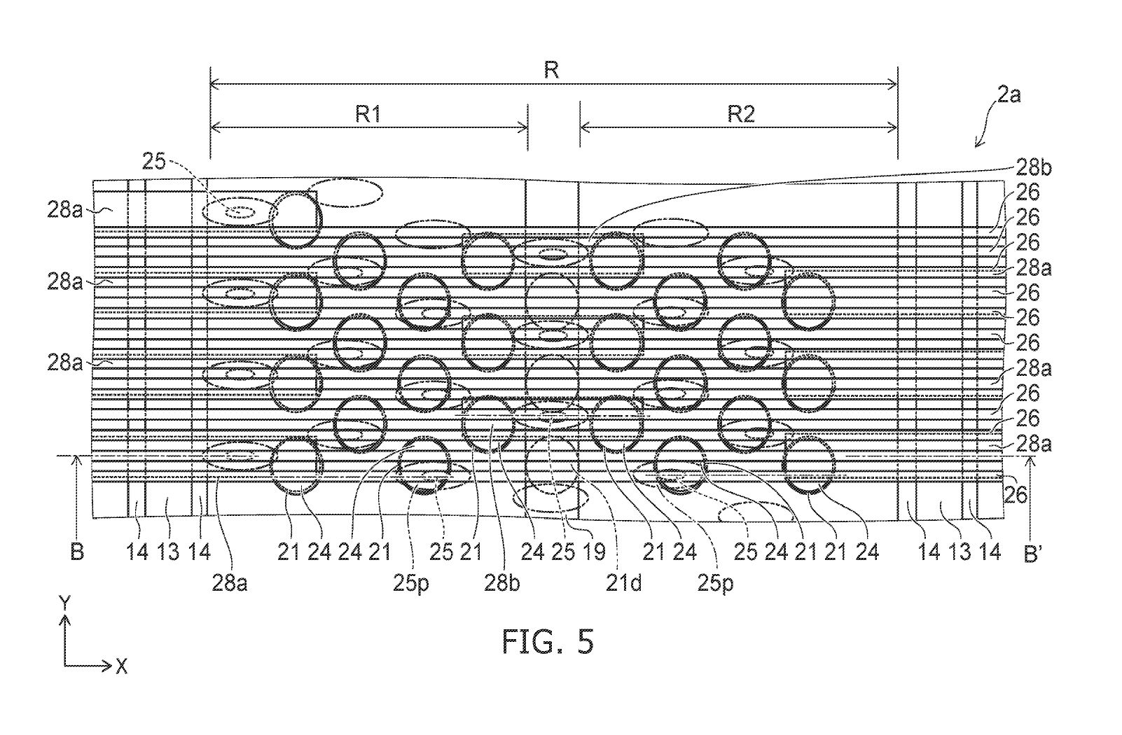

FIG. 5 is a plan view showing a semiconductor memory device according to this variation.

As shown in FIG. 5, the semiconductor memory device 2a according to this variation is different from the semiconductor memory device 2 (see FIGS. 3 and 4) according to the above second embodiment in the position of the plug 25 provided on the intermediate wiring 28a. More specifically, in the second embodiment, the plug 25 connected to the intermediate wiring 28a is placed on the X-direction central part of the intermediate wiring 28, i.e., directly above the source electrode 13. In contrast, in this variation, the plug 25 connected to the intermediate wiring 28a is placed in the sub-region R1 and on the region between the source electrode 13 and the contact 24 nearest to the source electrode 13.

This variation can also achieve an effect similar to that of the above second embodiment. As shown in this variation and the second embodiment, the plug 25 on the intermediate wiring can be placed at an arbitrary position within the range connectable to the intermediate wiring. Thus, the position of the plug 25 can be determined so that e.g. light exposure for forming the plug 25 is the easiest.

The configuration, operation, and effect of this variation other than the foregoing are similar to those of the above second embodiment.

### Third Embodiment

Next, a third embodiment is described.

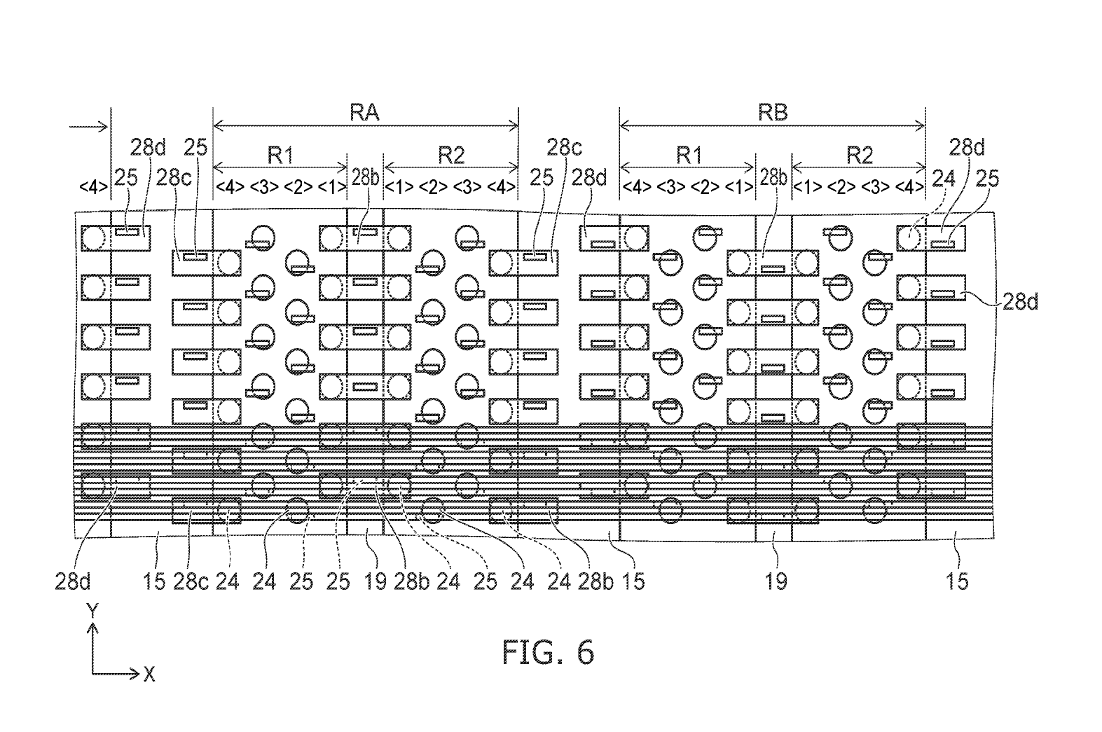

FIG. 6 is a plan view showing a semiconductor memory device according to this embodiment.

In FIG. 6, the plate-like member 15 is integrally shown for simplicity of illustration. Furthermore, the silicon pillars 21 are not shown because the silicon pillars 21 are placed directly below the contacts 24. Furthermore, only part of the bit lines 26 are shown, and the rest is not shown. Moreover, the plug 25 is shown as a rectangle. However, the actual shape of the plug 25 may be an oval. For convenience of illustration, the rows of contacts 24 in the first to fourth rows counted from the insulating member 19 are labeled with reference numerals <1>-<4>.

As shown in FIG. 6, the semiconductor memory device 3 according to this embodiment is different from the semiconductor memory device 2 (see FIG. 3) according to the above second embodiment in that instead of the intermediate wiring 28a, intermediate wirings 28c and 28d are provided directly above the source electrode 13. Furthermore, the semiconductor memory device 3 is different from the semiconductor memory device 2 (see FIG. 3) also in that the intermediate wiring 28b placed in one region R and the intermediate wiring 28b placed in the adjacent region R are shifted by half the pitch in the Y-direction.

The intermediate wiring 28c and the intermediate wiring 28d are spaced in the X-direction. The intermediate wiring 28c and the intermediate wiring 28d are shifted by half the pitch in the Y-direction, i.e., twice the arrangement pitch of the bit lines 26. One X-direction end part of the intermediate wirings 28c and 28d is placed directly above the plate-like member 15. The other X-direction end part is placed directly above the contact 24 in the row nearest to the plate-like member 15.

In the X-direction, the length of the intermediate wiring 28c is substantially equal to the length of the intermediate wiring 28d, but slightly shorter than the length of the intermediate wiring 28b. However, the difference between the length of the intermediate wiring 28b and the length of the intermediate wiring 28c is shorter than the difference between the length of the intermediate wiring 28a (see FIG. 3) and the length of the intermediate wiring 28b.

Also in this embodiment, as in the above second embodiment, the X-direction position of the contact 24 connected to the bit line 26 is periodically changed in units of four bit lines 26 arranged consecutively. However, the mode of the change is different between the regions R.

For instance, in the example shown in FIG. 6, in the sub-region R1 and the sub-region R2 of the region RA, the bit line 26 placed at the lowermost place in the figure is connected without the intermediary of the intermediate wiring with the contact 24 in the second row <2> from the insulating member 19. The bit line 26 placed at the second place from the bottom in the figure is connected through the intermediate wiring 28c with the contact 24 in the fourth row from the insulating member 19. The bit line 26 placed at the third place from the bottom in the figure is connected without the intermediary of the intermediate wiring with the contact 24 in the third row from the insulating member 19. The bit line 26 placed at the fourth place from the bottom in the figure is connected through the intermediate wiring 28b with the contact 24 in the first row from the insulating member 19. Also for the bit lines 26 placed at the fifth and subsequent places from the bottom in the figure, the configuration of the arrangement is periodically changed in a similar pattern. More specifically, in the region RA, the contact 24 connected to the bit line 26 belongs to the row changing in the order of <2>, <4>, <3>, and <1>. On the other hand, in the region RB, the contact 24 connected to the bit line 26 belongs to the row changing in the order of <1>, <3>, <2>, and <4>.

Furthermore, the contact 24 connected with one bit line 26 also belongs to a different row between the regions R. In the example shown in FIG. 6, for the first, second, fifth, sixth, . . . , (4n+1)-th, (4n+2)-th bit lines 26 (n being an integer of 0 or more), the contact 24 connected therewith belongs to the row changing in the order of <4>, <3>, <2>, and <1> from left to right in the figure, and this is repeated. On the other hand, for the third, fourth, seventh, eighth, . . . , (4n+3)-th, (4n+4)-th bit lines 26, the contact 24 connected therewith belongs to the row changing in the order of <1>, <2>, <3>, and <4> from left to right in the figure, and this change is repeated. Thus, in the semiconductor memory device 3, the adjacent regions R are not identical in structure. The structure is periodically changed in fundamental units of four regions R arranged consecutively in the X-direction.

Next, the effect of this embodiment is described.

In this embodiment, in contrast to the above second embodiment, intermediate wirings 28c and 28d spaced from each other in the X-direction are provided on the source electrode 13. Thus, the length of the intermediate wirings placed directly below one bit line 26 can be made uniform, including the intermediate wiring 28b provided on the insulating member 19. Accordingly, the length of the intermediate wirings connected to each bit line 26 can be made uniform. Furthermore, the length of the intermediate wirings opposed to one bit line 26 and not connected thereto through the plug 25 can also be made uniform. Thus, the wiring capacitance of each bit line 26 can be made uniform. As a result, the delay amount of signals flowing on the bit line 26 can be made uniform. This stabilizes the operation of the semiconductor memory device 3.

In this embodiment, the position of the intermediate wiring 28c and the position of the intermediate wiring 28d are shifted by half the pitch in the Y-direction. The position of the intermediate wiring 28b in the Y-direction is shifted by half the pitch between the adjacent regions R. This elongates the distance between the intermediate wirings and facilitates forming the intermediate wirings.

The configuration, operation, and effect of this embodiment other than the foregoing are similar to those of the above second embodiment.

The embodiments described above can realize a semiconductor memory device facilitating miniaturization of the planar structure.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention. Additionally, the embodiments described above can be combined mutually.

What is claimed is:

1. A semiconductor memory device comprising:
a plurality of first plate-like members extending in a first direction, the plurality of first plate-like members being spaced from each other in a second direction, and the second direction crossing the first direction;
a first wiring placed between two adjacent ones of the plurality of first plate-like members, and the first wiring extending in the first direction;
a second plate-like member placed on the first wiring, and the second plate-like member extending in the first direction;
a second wiring placed between one of the first plate-like members and the second plate-like member, and the second wiring extending in the first direction;
first to third semiconductor pillars extending in a third direction, the third direction crossing both the first direction and the second direction, and the first to third semiconductor pillars piercing the first wiring and the second wiring;
a memory film provided between the first wiring and one of the first to third semiconductor pillars;
first to third contacts provided on the first to third semiconductor pillars, and the first to third contacts being connected to the first to third semiconductor pillars, respectively;
first to third plugs provided on the first to third contacts, the first to third plugs being connected to the first to third contacts, respectively, central axes of the first to third plugs being shifted with respect to central axes of the first to third contacts, respectively, the first to third plugs being arranged in this order in the second direction, and distance between the central axis of the first plug and the central axis of the second plug in the second direction being different from distance between the central axis of the second plug and the central axis of the third plug in the second direction; and
third wirings provided on the first to third plugs, the third wirings extending in the second direction, and the third wirings being connected to the first to third plugs, respectively.

2. The device according to claim 1, wherein
distance between the first semiconductor pillar and one of the plurality of first plate-like members is shorter than distance between the first semiconductor pillar and the second plate-like member,
the central axis of the first plug is shifted to the plurality of first plate-like members side with respect to the central axis of the first contact,
distance between the third semiconductor pillar and the second plate-like member is shorter than distance between the third semiconductor pillar and one of the plurality of first plate-like members, and
the central axis of the third plug is shifted to the second plate-like member side with respect to the central axis of the third contact.

3. The device according to claim 1, wherein the central axis of the first contact is shifted to one of the first plate-like member and the second plate-like member nearer to the first semiconductor pillar with respect to central axis of the first semiconductor pillar.

4. The device according to claim 1, further comprising:
a first intermediate wiring connected between the first contact and the first plug,
wherein the second contact is in contact with the second plug.

5. The device according to claim 4, wherein distance between the first contact and one of the first plate-like member and the second plate-like member nearer to the first contact is shorter than distance between the second contact and one of the first plate-like member and the second plate-like member nearer to the second contact.

6. The device according to claim 4, further comprising:
a fourth semiconductor pillar extending in the third direction, and the fourth semiconductor pillar piercing the first wiring and the second wiring; and
a fourth contact provided on the fourth semiconductor pillar, and the fourth contact being connected to the fourth semiconductor pillar,
wherein the fourth contact is connected to the first intermediate wiring.

7. The device according to claim 6, wherein
distance between the first semiconductor pillar and one of the plurality of first plate-like member is shorter than distance between the first semiconductor pillar and the second plate-like member,
one of the plurality of first plate-like members is placed between the first semiconductor pillar and the fourth semiconductor pillar, and
the first intermediate wiring is placed astride one of the plurality of first plate-like members.

8. The device according to claim 7, further comprising:
a fifth semiconductor pillar extending in the third direction, and the fifth semiconductor pillar piercing the first wiring and the second wiring;
a sixth semiconductor pillar extending in the third direction, and the sixth semiconductor pillar piercing the first wiring and the second wiring, the second plate-like member being placed between the fifth semiconductor pillar and the sixth semiconductor pillar;
a fifth contact provided on the fifth semiconductor pillar, and the fifth contact being connected to the fifth semiconductor pillar;
a sixth contact provided on the sixth semiconductor pillar, and the sixth contact being connected to the sixth semiconductor pillar;
a second intermediate wiring placed astride the second plate-like member, and the second intermediate wiring being connected to the fifth contact and the sixth contact; and
a fourth plug connected between the second intermediate wiring and the third wiring.

9. The device according to claim 6, wherein
distance between the first semiconductor pillar and the second plate-like member is shorter than distance between the first semiconductor pillar and one of the plurality of first plate-like members,
the second plate-like member is placed between the first semiconductor pillar and the fourth semiconductor pillar, and
the first intermediate wiring is provided astride the second plate-like member.

10. The device according to claim 9, further comprising:
a fifth semiconductor pillar extending in the third direction, and the fifth semiconductor pillar piercing the first wiring and the second wiring;
a sixth semiconductor pillar extending in the third direction, and the sixth semiconductor pillar piercing the first wiring and the second wiring, one of the plurality of first plate-like members being provided between the fourth semiconductor pillar and the fifth semiconductor pillar;
a fifth contact provided on the fifth semiconductor pillar, and the fifth contact being connected to the fifth semiconductor pillar;
a sixth contact provided on the sixth semiconductor pillar, and the sixth contact being connected to the sixth semiconductor pillar;
a second intermediate wiring provided astride one of the plurality of first plate-like members, and the second intermediate wiring being connected to the fifth contact and the sixth contact; and
a fourth plug connected between the second intermediate wiring and the third wiring.

11. The device according to claim 9, further comprising:
a fifth semiconductor pillar extending in the third direction, and the fifth semiconductor pillar piercing the first wiring and the second wiring;
a sixth semiconductor pillar extending in the third direction, the sixth semiconductor pillar piercing the first wiring and the second wiring, and one of the first plate-like members being placed between the fifth semiconductor pillar and the sixth semiconductor pillar;
a fifth contact provided on the fifth semiconductor pillar, and the fifth contact being connected to the fifth semiconductor pillar;
a sixth contact provided on the sixth semiconductor pillar, and the sixth contact being connected to the sixth semiconductor pillar;
a second intermediate wiring with a first end part placed directly above one of the plurality of first plate-like members and a second end part connected to the fifth contact;
a third intermediate wiring with a first end part placed directly above one of the plurality of first plate-like members and a second end part connected to the sixth contact;
a fourth plug connected between the second intermediate wiring and the third wiring; and
a fifth plug connected between the third intermediate wiring and the third wiring.

12. The device according to claim 11, wherein
the second intermediate wiring and the third intermediate wiring are spaced in the second direction, and
position of the second intermediate wiring and position of the third intermediate wiring in the first direction are different from each other.

13. The device according to claim 1, further comprising:
a conductive member provided below the plurality of first plate-like members and the first wiring,
wherein
one of the plurality of first plate-like members includes:
an electrode plate connected to the conductive member; and
an insulating film provided on both sides in the second direction of the electrode plate, and
the second plate-like member is formed from an insulating material.

14. A semiconductor memory device comprising:
a plurality of first plate-like members extending in a first direction, the plurality of first plate-like members being spaced from each other in a second direction, and the second direction crossing the first direction;
a first wiring placed between two adjacent ones of the plurality of first plate-like members, and the first wiring extending in the first direction;
a second plate-like member placed on the first wiring, and the second plate-like member extending in the first direction;
a second wiring placed between one of the plurality of first plate-like members and the second plate-like member, and the second wiring extending in the first direction;
a plurality of semiconductor pillars extending in a third direction, the third direction crossing both the first direction and the second direction, and the plurality of semiconductor pillars piercing the first wiring and the second wiring;
a memory film provided between the first wiring and one of the plurality of semiconductor pillars;
a plurality of contacts provided on the semiconductor pillars, the plurality of contacts being connected to the semiconductor pillars, respectively, the plurality of contacts being arranged in m rows each (m being an integer of 3 or more) on both sides of the second plate-like member for each region between two adjacent ones of the plurality of first plate-like members, and each row extending along the first direction;
a first intermediate wiring provided astride one of the plurality of first plate-like members and on a pair of the contacts in the m-th row counted from the second plate-like member, the pair of the contacts in the m-th row sandwiching the one of the plurality of first plate-like members, and the first intermediate wiring being connected to the pair of the contacts in the m-th row;
a second intermediate wiring provided astride the second plate-like member and on a pair of the contacts in the first row counted from the second plate-like member, the pair of the contacts in the first row sandwiching the second plate-like member, and the second intermediate wiring being connected to the pair of the contacts in the first row;
a first plug provided on the first intermediate wiring, and the first plug being connected to the first intermediate wiring;
a second plug provided on the second intermediate wiring, and the second plug being connected to the second intermediate wiring;
third plugs in contact with upper surfaces of the contacts in the second to (m−1)-th rows counted from the second plate-like member; and
m third wirings extending in the second direction, and the m third wirings being connected to the first plug, the second plug, and the third plugs, respectively.

15. The device according to claim 14, wherein arrangement pitch of the first intermediate wirings and arrangement pitch of the second intermediate wirings in the first direction are m times arrangement pitch of the third wirings.

16. The device according to claim 14, wherein the m is an even number, and position of the first intermediate wiring and position of the second intermediate wiring in the first direction are different from each other.

17. The device according to claim 14, wherein position in the second direction of the contact connected to the third wiring is periodically changed in units of m of the third wirings arranged consecutively, and mode of the change is identical between the regions.

18. A semiconductor memory device comprising:
a plurality of first plate-like members extending in a first direction, and the plurality of first plate-like members being spaced from each other in a second direction, and the second direction crossing the first direction;
a first wiring placed between two adjacent ones of the first plate-like members, and the first wiring extending in the first direction;
a second plate-like member placed on the first wiring, and the second plate-like member extending in the first direction;
a second wiring placed between one of the plurality of first plate-like members and the second plate-like member, and the second wiring extending in the first direction;
a plurality of semiconductor pillars extending in a third direction, the third direction crossing both the first direction and the second direction, and the plurality of semiconductor pillars piercing the first wiring and the second wiring;
a memory film provided between the first wiring and one of the semiconductor pillars;
a plurality of contacts provided on the semiconductor pillars, the plurality of contacts being connected to the semiconductor pillars, respectively, the contacts being arranged in 2×m rows (m being an integer of 3 or more) extending along the first direction for each region between two adjacent ones of the first plate-like members, and the second plate-like member being placed between the m-th row of the contacts and the (m+1)-th row of the contacts counted from one of the first plate-like members;
a first intermediate wiring with a first end part in the second direction placed on one of the plurality of first plate-like members and a second end part in the second direction connected to the contact in the first row;
a second intermediate wiring with a first end part in the second direction connected to the contact in the m-th row, a central part in the second direction placed directly above the second plate-like member, and a second end part in the second direction connected to the contact in the (m+1)-th row;
a third intermediate wiring with a first end part in the second direction placed on one of the plurality of first plate-like members and a second end part in the second direction connected to the contact in the (2×m)-th row;
a first plug connected to the first intermediate wiring;
a second plug connected to the second intermediate wiring;
a third plug connected to the third intermediate wiring;
fourth plugs in contact with upper surfaces of the contacts in the second to (m−1)-th and (m+2)-th to (2×m)-th rows; and
m third wirings extending in the second direction, and the m third wirings being connected to the first plug, the second plug, the third plug, and the fourth plugs.

19. The device according to claim 18, wherein position in the second direction of the contact connected to the third wiring is periodically changed in units of m of the third wirings arranged consecutively, and mode of the change is different between the regions adjacent in the second direction.

20. The device according to claim 18, wherein the semiconductor pillars are placed at part of lattice points of a virtual lattice formed from first straight lines and second straight lines, the first straight lines and the second straight lines lying in a plane parallel to the first direction and the second direction and extending in directions crossing the first direction and the second direction and crossing each other.
